(19) United States
(12) Patent Application Publication
(10) Pub. No.: US 2012/0147971 A1
(43) Pub. Date: Jun. 14, 2012

(54) CODEWORD ADAPTATION FOR VARIABLE LENGTH CODING

(75) Inventors: Wei-Jung Chien, San Diego, CA (US); Xianglin Wang, San Diego, CA (US); Marta Karczewicz, San Diego, CA (US); Liwei Guo, San Diego, CA (US)

(73) Assignee: QUALCOMM INCORPORATED, San Diego, CA (US)

(21) Appl. No.: 13/228,853

(22) Filed: Sep. 9, 2011

Related U.S. Application Data
(60) Provisional application No. 61/420,875, filed on Dec. 8, 2010.
(60) Provisional application No. 61/448,331, filed on Mar. 2, 2011.
(60) Provisional application No. 61/450,540, filed on Mar. 8, 2011.
(60) Provisional application No. 61/491,777, filed on May 31, 2011.

(51) Int. Cl. H04N 7/26; H03M 7/40

(52) U.S. Cl. 375/240.23; 341/67; 375/E07.144

(57) ABSTRACT

In one example, this disclosure describes a method of codeword adaptation for variable length coding. The method comprises applying a first codeword adaptation scheme to a first group of codewords of a variable length coding (VLC) table to change a mapping of codewords to events in the VLC table; and applying a second codeword adaptation scheme to a second group of codewords of the VLC table to change the mapping of the codewords to the events in the VLC table.

This application claims the benefit of U.S. Provisional Application No. 61/420,875, filed Dec. 8, 2010, which is hereby incorporated by reference in its entirety. This application also claims the benefit of U.S. Provisional Application No. 61/448,331, filed Mar. 2, 2011, which is hereby incorporated by reference in its entirety. This application also claims the benefit of U.S. Provisional Application No. 61/450,540, filed Mar. 8, 2011, which is hereby incorporated by reference in its entirety. This application also claims the benefit of U.S. Provisional Application No. 61/491,777, filed May 31, 2011, which is hereby incorporated by reference in its entirety.

### TECHNICAL FIELD

This disclosure relates to video coding.

### BACKGROUND

Digital video capabilities can be incorporated into a wide range of devices, including digital televisions, digital direct broadcast systems, wireless communication devices such as radio telephone handsets, wireless broadcast systems, personal digital assistants (PDAs), laptop or desktop computers, tablet computers, digital cameras, digital recording devices, video gaming devices, video game consoles, personal multimedia players, and the like. Such video devices may implement video compression techniques, such as those described in MPEG-2, MPEG-4, or ITU-T H.264/MPEG-4, Part 10, Advanced Video Coding (AVC), in order compress video data. Video compression techniques perform spatial and temporal prediction to reduce or remove redundancy inherent in video sequences. New standards, such as the High Efficiency Video Coding (HEVC) standard (which may ultimately be referred to as ITU-T H.265), continue to emerge and evolve.

Many video coding standards and techniques use block-based video coding. Block-based video coding techniques divide the video data of a video frame (or portion thereof) into video blocks and then encode the video blocks using predictive block-based compression techniques. The video blocks may be further divided into video block partitions. The video blocks (or partitions thereof) may be referred to as “coded units” and may be encoded using one or more video-specific encoding techniques as well as general data compression techniques.

With the emerging HEVC standard, largest coded units (LCUs) may be divided into smaller and smaller coded units (CUs) according to a quadtree partitioning scheme, and the different CUs may be further partitioned into so-called prediction units (PUs). The CUs (or the PUs) may be encoded using motion estimation, motion compensation, transform coding such as discrete cosine transforms (DCT) that occur with respect to transform units (TUs) having one or more possible transform sizes, quantization, and variable length coding. Syntax information is often signaled with encoded video data, e.g., in a video slice header or video block header, in order to inform the decoder how to decode the video data.

### SUMMARY

This disclosure describes techniques to apply codeword adaptation schemes to variable length coding (VLC) tables. A VLC table may be used to signal one or more coded events that are mapped to one or more codewords. Codeword adaptations may be applied to the VLC table to improve coding efficiency. For example, codeword adaptations may reassign more frequently coded events to shorter codewords. In this way, a video coding system may in average reduce the quantity of bits required to code all occurring events. In one example, techniques of the present disclosure may select and apply codeword adaptation schemes to a VLC table based on one or more thresholds to improve coding efficiency. Accordingly, the techniques of this disclosure may be applicable to the emerging ITU-T H.265 standard or other standards implement variable length coding techniques.

In one example, a method includes applying a first codeword adaptation scheme to a first group of codewords of a variable length coding (VLC) table to change a mapping of codewords to events in the VLC table; and applying a second codeword adaptation scheme to a second group of codewords of the VLC table to change the mapping of the codewords to the events in the VLC table.

In one example, an apparatus codes video data, the apparatus comprising a codec unit configured to: apply a first codeword adaptation scheme to a first group of codewords of a variable length coding (VLC) table to change a mapping of codewords to events in the VLC table; and apply a second codeword adaptation scheme to a second group of codewords of the VLC table to change the mapping of the codewords to the events in the VLC table.

In one example, a device codes video data, the device comprising: means for applying a first codeword adaptation scheme to a first group of codewords of a variable length coding (VLC) table to change a mapping of codewords to events in the VLC table; and means for applying a second codeword adaptation scheme to a second group of codewords of the VLC table to change the mapping of the codewords to the events in the VLC table.

In one example, a computer-readable storage medium comprises instructions that upon execution in a processor, cause the processor to code video data, wherein the instructions cause the processor to: apply a first codeword adaptation scheme to a first group of codewords of a variable length coding (VLC) table to change a mapping of codewords to events in the VLC table; and apply a second codeword adaptation scheme to a second group of codewords of the VLC table to change the mapping of the codewords to the events in the VLC table.

The details of one or more examples are set forth in the accompanying drawings and the description below. Other features, objects, and advantages will be apparent from the description and drawings, and from the claims.

### BRIEF DESCRIPTION OF DRAWINGS

FIG. 1 is a block diagram illustrating an example video encoding and decoding system 10 that may apply codeword adaptation schemes, in accordance with one or more aspects of the present disclosure.

FIG. 2 is a block diagram illustrating an example of video encoder that may apply codeword adaptation schemes, in accordance with one or more aspects of the present disclosure.

FIG. 3 is a block diagram illustrating an example of video decoder, which decodes an encoded video sequence, in accordance with one or more aspects of the present disclosure.

FIG. 4 is a flow diagram illustrating an example method to select and apply VLC techniques based the number of events in a VLC table, in accordance with one or more aspects of the present disclosure.

FIG. 5 is a flow diagram illustrating an example method to generate a threshold based the lengths of codewords in a VLC table, in accordance with one or more aspects of the present disclosure.

FIG. 6 is a flow diagram illustrating an example method to perform modified counter based adaptation on a VLC table, in accordance with one or more aspects of the present disclosure.

FIG. 7A is a flow diagram illustrating an example method to apply different adaptation schemes to different events in the same VLC table based on the ordering of the codewords and events in the table, in accordance with one or more aspects of the present disclosure.

FIG. 7B is a flow diagram illustrating an example method to map a first event associated with a higher-ordered codeword of a second group to a lower-ordered codeword of a first group, in accordance with one or more aspects of the present disclosure.

FIGS. 8A, 8B, 8C are diagrams illustrating example VLC tables, in accordance with one or more aspects of the present disclosure.

FIG. 9 is a flowchart illustrating a method to apply a first codeword adaptation scheme to groups of codewords and applying a second code table adaptation scheme to individual codewords within the groups of codewords, in accordance with one or more aspects of the present disclosure.

FIGS. 10A and 10B illustrate a first technique of applying multiple adaptation schemes to a codeword table, in accordance with one or more aspects of the present disclosure.

### DETAILED DESCRIPTION

This disclosure relates to techniques for applying codeword adaptation schemes to variable length coding (VLC) tables. Specifically, one or more codeword adaptation schemes may be applied to a VLC table to improve coding performance. For instance, a codeword adaptation scheme may assign more frequently occurring events to shorter codewords of a VLC table. In one example, an entropy encoding unit of a video encoder may use one or more VLC tables to code one or more events that represent, e.g., quantized transform coefficients. The entropy encoding unit may assign events to codewords in the VLC table such that more frequently occurring events are assigned to shorter codewords. In some examples, the entropy encoding unit may determine that the number of events stored in the VLC table satisfies a threshold. Consequently, the entropy encoding unit may select and apply a suitable codeword adaptation scheme that reassigns codewords to events associated with the VLC table for higher coding performance.

In the following description, VLC tables may be assumed to be arranged in such a manner that shorter codewords in a VLC table are given smaller codeword indexes, i.e. a shorter codeword is always located before a longer codeword inside a VLC table. If a VLC table is not arranged in such a manner, techniques described in this disclosure are still applicable after rearranging its codewords in the way described above.

To further improve coding efficiency, multiple codeword adaptation schemes may be applied to different groups of codewords of a VLC table. For example, an entropy encoding unit may apply a codeword adaptation scheme suitable to lower-ordered codewords (i.e. codewords with smaller indexes that are located at the beginning of a VLC table) of a VLC table to the lower-ordered codewords. The entropy encoding unit may apply a different, suitable codeword adaptation scheme to higher-ordered codewords. Techniques of the present disclosure may further enable, e.g., an entropy encoding unit to apply a codeword adaptation scheme to groups of codewords in a VLC table to change mappings of codewords within the groups to events associated with the VLC table. Additionally, the entropy encoding unit may apply another codeword adaptation scheme to individual codewords within the groups of codewords in the VLC table to change mappings of the codewords to the events within the groups in the VLC table. In this way, multiple, different codeword adaptation schemes may be applied to a VLC table to improve coding performance. Techniques of the present disclosure are generally applicable to any component of an encoder or decoder that may use variable length coding to encode events. The techniques of the present disclosure are further described herein.

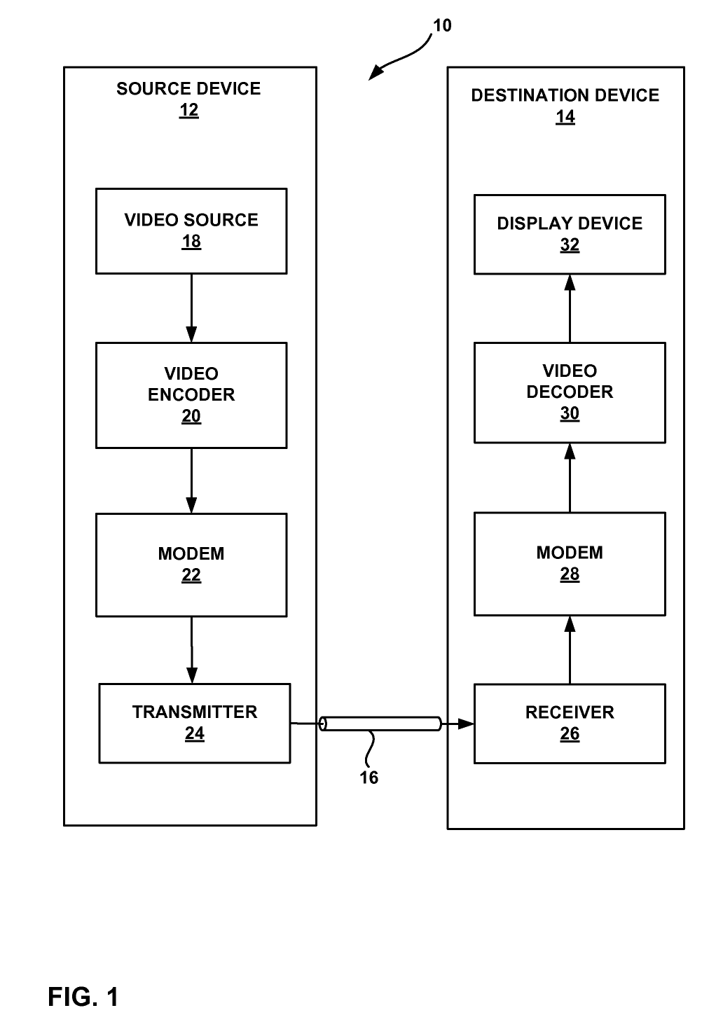

FIG. 1 is a block diagram illustrating an example video encoding and decoding system 10 that may apply codeword adaptation schemes during the video encoding or decoding processes, in accordance with one or more aspects of the present disclosure. As shown in FIG. 1, system 10 may include a source device 12 that transmits encoded video to a destination device 14 via a communication channel 16. Source device 12 and destination device 14 may comprise any of a wide range of devices. In some cases, source device 12 and destination device 14 may comprise wireless communication devices, such as wireless handsets, so-called cellular or satellite radiotelephones, or any wireless devices that can communicate video information over a communication channel 16, in which case communication channel 16 is wireless. The techniques of this disclosure, however, which concern selecting and applying codeword adaptation schemes based on one or more conditions during video encoding or video decoding, are not limited to wireless applications or settings.

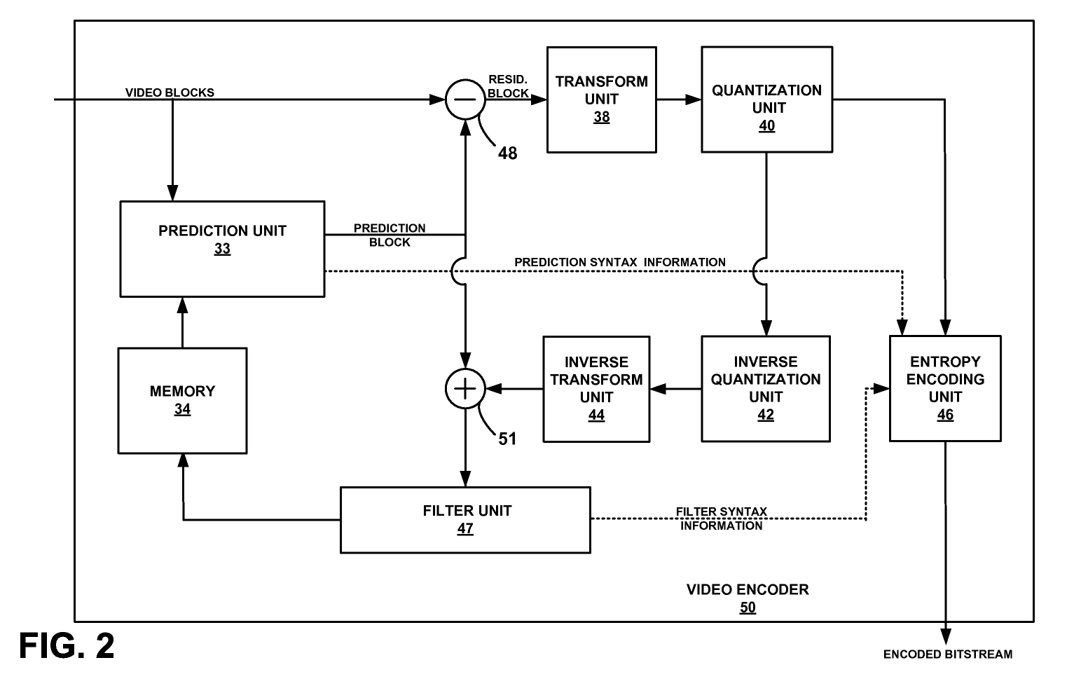

In the example of FIG. 1, source device 12 may include a video source 18, video encoder 20, a modulator/demodulator (modem) 22 and a transmitter 24. Destination device 14 includes a receiver 26, a modem 28, a video decoder 30, and a display device 32. In accordance with this disclosure, video encoder 20 of source device 12 may be configured to apply the techniques for selecting and applying VLC techniques based on one or more conditions. For example, techniques of the present disclosure may be applied to VLC tables used in prediction unit 33 and/or entropy encoding unit 46 of video encoder 20 as shown in FIG. 2. In one example, prediction unit 33 may generate syntax information that describes characteristics and/or processing of coded units. The syntax information may be coded using VLC coding techniques of the present disclosure. In another example, entropy encoding unit 46 of FIG. 2 may entropy code quantized and transformed residual coding units using VLC coding techniques of the present disclosure. Prediction unit 33, entropy encoding unit 46, and VLC coding techniques of the present disclosure are further described herein.

A source device and a destination device may include other components or arrangements. For example, source device 12 may receive video data from an external video source 18, such as an external camera. Likewise, destination device 14 may interface with an external display device, rather than including an integrated display device.

The illustrated system 10 of FIG. 1 is merely one example. Techniques for selecting and applying VLC techniques based on one or more conditions may be performed by any digital video encoding and/or decoding device. The techniques of this disclosure may be performed by both a video encoder/decoder, typically referred to as a “CODEC.” Moreover, the techniques of this disclosure may also be performed by a video preprocessor. Source device 12 and destination device 14 are merely examples of such coding devices in which source device 12 generates coded video data for transmission to destination device 14. In some examples, devices 12, 14 may operate in a substantially symmetrical manner such that each of devices 12, 14 include video encoding and decoding components. Hence, system 10 may support one-way or two-way video transmission between video devices 12, 14, e.g., for video streaming, video playback, video broadcasting, or video telephony.

Video source 18 of source device 12 may include a video capture device, such as a video camera, a video archive containing previously captured video, and/or a video feed from a video content provider. As a further alternative, video source 18 may generate computer graphics-based data as the source video, or a combination of live video, archived video, and computer-generated video. In some cases, if video source 18 is a video camera, source device 12 and destination device 14 may form so-called camera phones or video phones. As mentioned above, however, the techniques described in this disclosure may be applicable to video coding in general, and may be applied to wireless and/or wired applications. In each case, the captured, pre-captured, or computer-generated video may be encoded by video encoder 20. The encoded video information may then be modulated by modem 22 according to a communication standard, and transmitted to destination device 14 via transmitter 24. Modem 22 may include various mixers, filters, amplifiers or other components designed for signal modulation. Transmitter 24 may include circuits designed for transmitting data, including amplifiers, filters, and one or more antennas.

Receiver 26 of destination device 14 receives information over channel 16, and modem 28 demodulates the information. Again, the video encoding process may implement one or more of the techniques described herein to select and apply VLC techniques based on one or more conditions. The information communicated over channel 16 may include syntax information defined by video encoder 20, which is also used by video decoder 30, that includes syntax elements that describe characteristics and/or processing of coding units. Display device 32 displays the decoded video data to a user, and may comprise any of a variety of display devices such as a cathode ray tube (CRT), a liquid crystal display (LCD), a plasma display, an organic light emitting diode (OLED) display, or another type of display device.

In the example of FIG. 1, communication channel 16 may comprise any wireless or wired communication medium, such as a radio frequency (RF) spectrum or one or more physical transmission lines, or any combination of wireless and wired media. Communication channel 16 may form part of a packet-based network, such as a local area network, a wide-area network, or a global network such as the Internet. Communication channel 16 generally represents any suitable communication medium, or collection of different communication media, for transmitting video data from source device 12 to destination device 14, including any suitable combination of wired or wireless media. Communication channel 16 may include routers, switches, base stations, or any other equipment that may be useful to facilitate communication from source device 12 to destination device 14.

Video encoder 20 and video decoder 30 may operate according to a video compression standard, such as the emerging HEVC standard, alternatively referred to as H.265. The techniques of this disclosure, however, are not limited to any particular coding standard. Other examples include the ITU-T H.264 standard, alternatively referred to as MPEG-4, Part 10, Advanced Video Coding (AVC). Although not shown in FIG. 1, in some aspects, video encoder 20 and video decoder 30 may each be integrated with an audio encoder and decoder, and may include appropriate MUX-DEMUX units, or other hardware and software, to handle encoding of both audio and video in a common data stream or separate data streams. If applicable, MUX-DEMUX units may conform to the ITU H.223 multiplexer protocol, or other protocols such as the user datagram protocol (UDP).

Video encoder 20 and video decoder 30 each may be implemented as any of a variety of suitable encoder circuitry, such as one or more microprocessors, digital signal processors (DSPs), application specific integrated circuits (ASICs), field programmable gate arrays (FPGAs), discrete logic, software, hardware, firmware or any combinations thereof. Each of video encoder 20 and video decoder 30 may be included in one or more encoders or decoders, either of which may be integrated as part of a combined encoder/decoder (CODEC) in a respective camera, computer, mobile device, subscriber device, broadcast device, set-top box, server, or the like.

A video sequence typically includes a series of video frames. A group of pictures (GOP) generally comprises a series of one or more video frames. A GOP may include syntax data in a header of the GOP, a header of one or more frames of the GOP, or elsewhere, that describes a number of frames included in the GOP. Each frame may include frame syntax data that describes an encoding mode for the respective frame.

Video encoder 20 typically operates on video blocks within individual video frames in order to encode the video data. A video block may correspond to a macroblock or a partition of a macroblock. The video blocks may have fixed or varying sizes, and may differ in size according to a specified coding standard. Each video frame may include a plurality of slices. Each slice may include a plurality of macroblocks, which may be arranged into partitions, also referred to as sub-blocks.

Macroblocks are one type of video block defined by the ITU H.264 standard and other standards. Macroblocks typically refer to 16 by 16 blocks of data. The ITU-T H.264 standard supports intra prediction in various block sizes, such as 16 by 16, 8 by 8, or 4 by 4 for luma components, and 8 by 8 for chroma components, as well as inter prediction in various block sizes, such as 16 by 16, 16 by 8, 8 by 16, 8 by 8, 8 by 4, 4 by 8 and 4 by 4 for luma components and corresponding scaled sizes for chroma components.

The emerging HEVC standard defines new terms for video blocks. In particular, with HEVC, video blocks (or partitions thereof) may be referred to as “coded units.” With the HEVC standard, largest coded units (LCUs) may be divided into smaller and smaller coded units (CUs) according to a quadtree partitioning scheme, and the different CUs that are defined in the scheme may be further partitioned into so-called prediction units (PUs). The LCUs, CUs, and PUs are all video blocks within the meaning of this disclosure. Other types of video blocks may also be used, consistent with the HEVC standard or other video coding standards. Thus, the phrase “video blocks” refers to any size of video block. Moreover, video blocks may sometimes refer to blocks of video data in the pixel domain, or blocks of data in a transform domain such as a discrete cosine transform (DCT) domain, a domain similar to DCT, a wavelet domain, or the like. In most cases consistent with the techniques of this disclosure, however, the filtering of this disclosure may occur in the pixel domain.

Video encoder 20 may perform predictive coding in which a video block being coded is compared to a predictive frame (or other CU) in order to identify a predictive block. This process of predictive coding may be referred to as motion estimation and motion compensation. Motion estimation estimates video motion of the video block relative to one or more predictive blocks of one or more predictive frames (or other CUs). Motion compensation generates the desired predictive block from the one or more predictive frames or other CUs. Motion compensation often includes an interpolation process in which interpolation filtering is performed to generate predictive data at fractional precision.

After generating the predictive block, the differences between the current video block being coded and the predictive block are coded as residual information, i.e., a “residual,” and prediction syntax (such as a motion vector) is used to identify the predictive block. In some examples, syntax elements may mapped to codewords stored in a VLC table using VLC techniques. VLC codeword adaptation schemes of the present disclosure may be applied to the VLC table as further described herein.

In some examples, the residual may be transformed and quantized. Transform techniques may comprise a DCT process or conceptually similar process, integer transforms, wavelet transforms, or other types of transforms. In a DCT process, as an example, the transform process converts a set of pixel values (e.g., residual values) into transform coefficients, which may represent the energy of the pixel values in the frequency domain. The emerging HEVC standard allows for transformations according to transform units (TUs), which may be different for different CUs. The TUs are typically sized according to the size of CUs defined for a partitioned LCU, although this may not always be the case. Quantization is typically applied on the transform coefficients, and generally involves a process that limits the number of bits associated with any given transform coefficient.

Following transform and quantization, entropy coding may be performed on the quantized and transformed residual information. Syntax elements, such as filter syntax information and prediction vectors defined during the encoding, may also be included in the entropy coded bitstream. In general, entropy coding comprises one or more processes that collectively compress a sequence of quantized transform coefficients and/or other syntax information. Scanning techniques, such as zig-zag scanning techniques, are performed on the quantized transform coefficients in order to define one or more serialized one-dimensional vectors of coefficients from two-dimensional video blocks. The scanned coefficients are then entropy coded along with any syntax information, e.g., via content adaptive variable length coding (CAVLC), context adaptive binary arithmetic coding (CABAC), or another entropy coding process.

Video encoder 20 and video decoder 30 each may be implemented as any of a variety of suitable encoder or decoder circuitry, as applicable, such as one or more microprocessors, digital signal processors (DSPs), application specific integrated circuits (ASICs), field programmable gate arrays (FPGAs), discrete logic circuitry, software, hardware, firmware or any combinations thereof. Each of video encoder 20 and video decoder 30 may be included in one or more encoders or decoders, either of which may be integrated as part of a combined video encoder/decoder (CODEC). An apparatus including video encoder 20 and/or video decoder 30 may comprise an integrated circuit, a microprocessor, and/or a wireless communication device, such as a cellular telephone. As discussed in FIG. 1 and throughout this disclosure, a codec unit may include video encoder 20 and/or video decoder 30.

FIG. 2 is a block diagram illustrating a video encoder 50 consistent with this disclosure. Video encoder 50 may correspond to video encoder 20 of source device 12 as shown in FIG. 1, or a video encoder of a different device. As shown in FIG. 2, video encoder 50 includes a prediction unit 33, adders 48 and 51, and a memory 34. Video encoder 50 also includes a transform unit 38 and a quantization unit 40, as well as an inverse quantization unit 42 and an inverse transform unit 44. Video encoder 50 also includes an entropy encoding unit 46, and a filter unit 47.

Generally, during the encoding process, video encoder 50 receives a video block to be coded, and prediction unit 33 performs predictive coding techniques. The video block may comprise a CU or a PU as outlined above, or may generally comprise any block of video data consistent with a block-based video coding technique or standard. For inter coding, prediction unit 33 compares the video block to be encoded to various blocks in one or more video reference frames or slices (e.g., one or more “list” of reference data) in order to define a predictive block. For intra coding, prediction unit 33 generates a predictive block based on neighboring data within the same coded unit. Prediction unit 33 outputs the prediction block and adder 48 subtracts the prediction block from the video block being coded in order to generate a residual block.

For inter coding, prediction unit 33 may comprise motion estimation and motion compensation units that identify a motion vector that points to a prediction block and generates the prediction block based on the motion vector. Typically, motion estimation is considered the process of generating the motion vector, which estimates motion. For example, the motion vector may indicate the displacement of a predictive block within a predictive frame relative to the current block being coded within the current frame. Motion compensation is typically considered the process of fetching or generating the predictive block based on the motion vector determined by motion estimation. For intra coding, prediction unit 33 generates a predictive block based on neighboring data within the same frame. One or more intra-prediction modes may define how an intra prediction block can be defined.

Motion compensation for inter-coding may include interpolations to sub-pixel resolution. Accordingly prediction unit 33 may include one or more interpolation filters to interpolate prediction data to half-pixel resolution, quarter-pixel resolution, or even finer resolution. This permits the motion estimation process to estimate motion of video blocks to such sub-pixel resolution.

After prediction unit 33 outputs the prediction block, and after adder 48 subtracts the prediction block from the video block being coded in order to generate a residual block, transform unit 38 applies a transform to the residual block. The transform may comprise a discrete cosine transform (DCT) or a conceptually similar transform such as that defined by the ITU H.264 standard or the HEVC standard. In some examples, consistent with the HEVC standard, the size of the transform may vary within a CU or PU, depending on the level of TU partitioning that occurs with respect to a given CU. Transform units (TUs) may be defined in order to set the transform size. Wavelet transforms, integer transforms, sub-band transforms or other types of transforms could also be used. In any case, transform unit applies the transform to the residual block, producing a block of residual transform coefficients. The transform, in general, may convert the residual information from a pixel domain to a frequency domain.

Quantization unit 40 then quantizes the residual transform coefficients to further reduce bit rate. Quantization unit 40, for example, may limit the number of bits used to code each of the coefficients. After quantization, entropy encoding unit 46 may scan and entropy encode the data. For example, entropy encoding unit 46 may scan the quantized coefficient block from a two-dimensional representation to one or more serialized one-dimensional vectors. The scan order may be pre-programmed to occur in a defined order (such as zig-zag scanning or another pre-defined order), or possibly adaptively defined based on previous coding statistics. Following this scanning process, entropy encoding unit 46 encodes the quantized transform coefficients (along with any syntax elements such as the filter syntax information described herein) according to an entropy coding methodology. Examples of entropy coding techniques that may be used by entropy encoding unit 46 include context adaptive variable length coding (CAVLC) and context adaptive binary arithmetic coding (CABAC). Syntax elements included in the entropy coded bitstream may include prediction syntax from prediction unit 33, such as motion vectors for inter coding or prediction modes for intra coding. Syntax elements included in the entropy coded bitstream may also include filter information from filter unit 47, which can be encoded in the manner described herein.

CAVLC is one type of entropy coding technique supported by the ITU H.264 standard and the emerging HEVC standard, which may be applied on a vectorized basis by entropy encoding unit 46. CAVLC uses variable length coding (VLC) tables in a manner that effectively compresses syntax elements such as serialized “runs” of transform coefficients. CABAC is another type of entropy coding technique supported by the ITU H.264 standard or the HEVC standard, which may be applied on a vectorized basis by entropy encoding unit 46. CABAC may involve several stages, including binarization, context model selection, and binary arithmetic coding. In this case, entropy encoding unit 46 codes transform coefficients and syntax elements according to CABAC. Many other types of entropy coding techniques also exist, and new entropy coding techniques will likely emerge in the future. This disclosure is not limited to any specific entropy coding technique. A more detailed description of entropy encoding unit 46 follows.

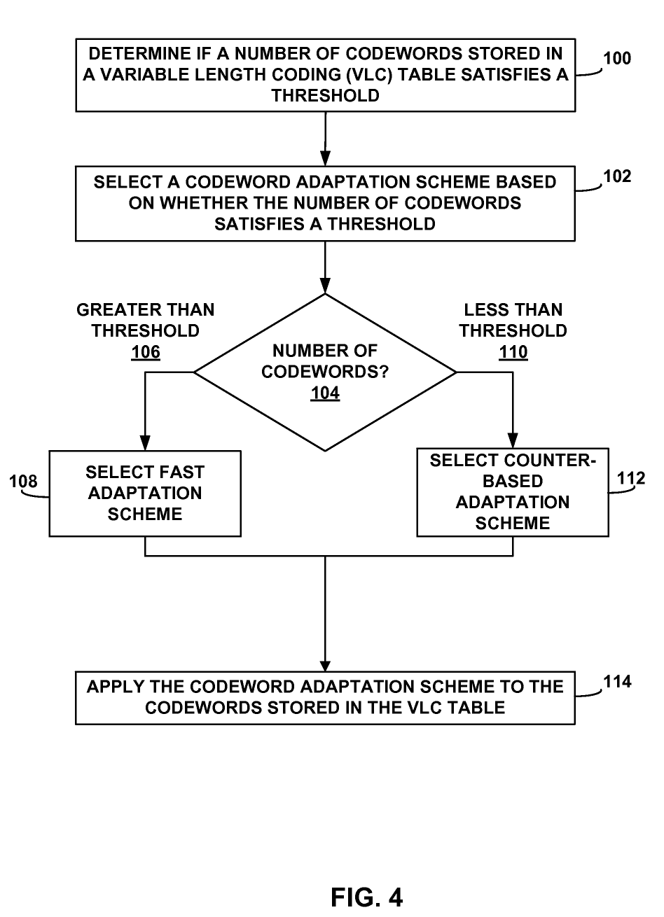

In some examples, entropy encoding unit 46 may generate one or more codeword mapping tables. A codeword mapping table may store one or more mappings of codewords to events. For instance, events may refer generally to any data generated by a video encoder. In one example, events may represent quantized transform coefficients. Each event may be mapped to a codeword in the codeword table. In some examples, entropy encoding unit 46 may map more frequently occurring events to shorter codewords of the codeword table. In this way in average a smaller number of bits is required to code all occurring events. FIGS. 4-10 describe various codeword adaptation schemes that may be applied to codeword tables to reassign codewords to events to improve coding efficiency.

Following the entropy coding by entropy encoding unit 46, the encoded video may be transmitted to another device or archived for later transmission or retrieval. Again, the encoded video may comprise the entropy coded vectors and various syntax information (including the filter information described herein), which can be used by the decoder to properly configure the decoding process. Inverse quantization unit 42 and inverse transform unit 44 apply inverse quantization and inverse transform, respectively, to reconstruct the residual block in the pixel domain. Summer 51 adds the reconstructed residual block to the prediction block produced by prediction unit 33 to produce a reconstructed video block for storage in memory 34. Prior to such storage, however, filter unit 47 may apply filtering to the video block to improve video quality. Such filtering by filter unit 47 may reduce artifacts and smooth pixel boundaries. Moreover, filtering may improve compression by generating predictive video blocks that comprise close matches to video blocks being coded.

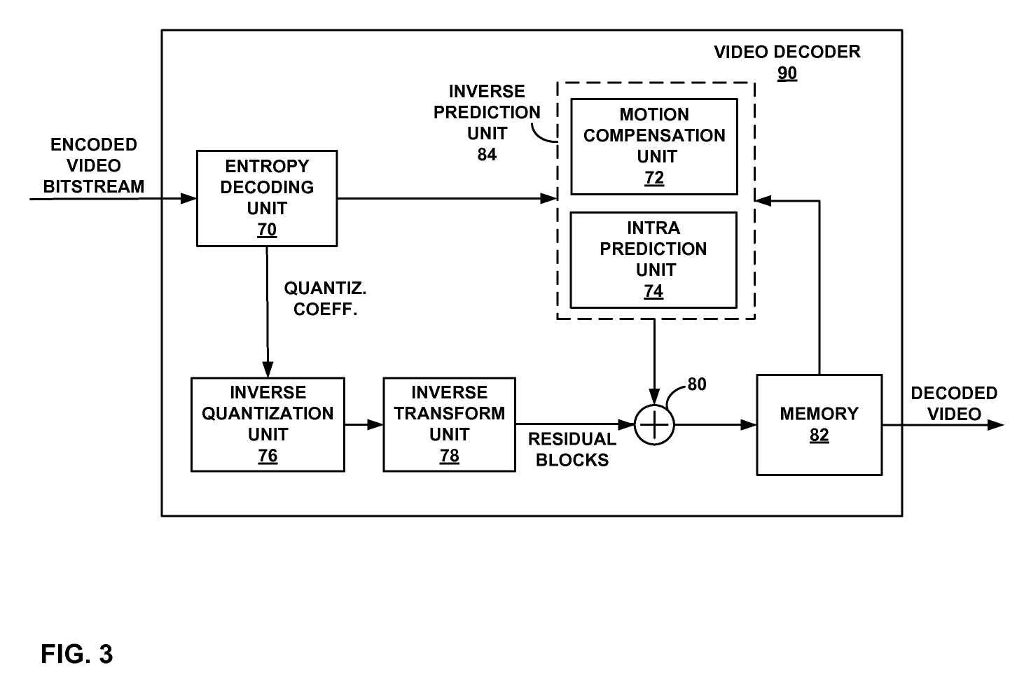

FIG. 3 is a block diagram illustrating an example of video decoder 90, which decodes an encoded video sequence, in accordance with one or more aspects of the present disclosure. In some examples, video decoder 30 of FIG. 1 may be a video decoder 90 as shown in FIG. 3. In the example of FIG. 3, video decoder 90 includes an entropy decoding unit 70, motion compensation unit 72, intra prediction unit 74, inverse quantization unit 76, inverse transformation unit 78, memory 82 and summer 80. Motion compensation unit 72 and intra prediction unit 74 may collectively be referred to as an inverse prediction unit 84 in some examples. Video decoder 90 may, in some examples, perform a decoding pass generally reciprocal to the encoding pass described with respect to video encoder 20 (FIG. 2). Motion compensation unit 72 may generate prediction data based on motion vectors received from entropy decoding unit 70.

Motion compensation unit 72 may use motion vectors received in the bitstream to identify a prediction CU in reference frames in memory 82. Intra prediction unit 74 may use intra prediction modes received in the bitstream to form a prediction CU from spatially adjacent blocks. Inverse quantization unit 76 inverse quantizes, i.e., de-quantizes, the quantized CU coefficients provided in the bitstream and decoded by entropy decoding unit 70. The inverse quantization process may also include use of a quantization parameter QP_{Y} calculated by encoder 50 for each LCU to determine a degree of quantization and, likewise, a degree of inverse quantization that should be applied.

Inverse transform unit 78 applies an inverse transform, e.g., an inverse DCT, an inverse integer transform, or a conceptually similar inverse transform process, to the transform coefficients in order to produce residual CUs in the pixel domain. Motion compensation unit 72 produces motion compensated CUs, possibly performing interpolation based on interpolation filters. Identifiers for interpolation filters to be used for motion estimation with sub-pixel precision may be included in the syntax elements. Motion compensation unit 72 may use interpolation filters as used by video encoder 20 during encoding of the video block to calculate interpolated values at sub-pixel locations of a reference CU. Motion compensation unit 72 may determine the interpolation filters used by video encoder 20 according to received syntax information and use the interpolation filters to produce predictive CUs.

Motion compensation unit 72 uses some of the syntax information to determine sizes of LCUs used to encode frame(s) of the encoded video sequence, partition information that describes how each LCU of a frame of the encoded video sequence is partitioned, modes indicating how each partition is encoded, one or more reference frames (or lists) for each inter-encoded LCU or partition, and other information to decode the encoded video sequence.

Summer 80 sums the residual blocks with the corresponding prediction blocks generated by motion compensation unit 72 or intra-prediction unit to form decoded CUs. If desired, a deblocking filter may also be applied to filter the decoded CUs in order to remove blockiness artifacts. The decoded CUs are then stored in memory 82, which provides reference CUs for subsequent motion compensation and also produces decoded video for presentation on a display device (such as display device 32 of FIG. 1).

The HEVC Test Model (HM) Reference Software (or TMuC) may be used as the reference software for the emerging HEVC coding standard. Codeword adaptation for VLC is currently used in HM in order to achieve better coding performance. For instance, as described above, entropy encoding unit 46 of FIG. 2 may use VLC coding techniques to reduce the number of bits needed to communicate various events. Entropy encoding unit 46 may maintain one or more codeword mapping tables that store one or more mappings of codewords to events, e.g., codewords to quantized transform coefficient syntaxes. As described in various examples herein, codeword adaptation schemes of the present disclosure will be illustrated in codeword tables of entropy encoding unit 46. However, such techniques may be applied in any one or more components of video encoder 50 and/or video decoder 90 as shown in FIGS. 1-3. For example, codeword adaptation schemes for VLC may be applied to syntax elements generated by prediction unit 33 or filtering information generated by filter unit 47.

Codeword adaptation is the technique that for a fixed VLC table, each codeword may represent different symbols or events at different times by changing the mapping of codewords to symbols or events. For example, a VLC table with three codewords, (1, 01, and 00) may be used to represent three events (A, B and C). Events A, B, and C may represent values of quantized transform coefficients that entropy encoding unit 46 receives from quantization unit 40. Depending on the occurrence probability of the events, 1 may be used to represent A, 01 for B, and 00 for C. If the statistics of the events changes, e.g., event B occurs more frequently than events A and C, entropy encoding unit 46 may perform codeword assignment such that 1 is reassigned to B, 01 to A, and 00 to C in order to achieve better performance. In a separate example, VLC codewords may comprise syntax elements of a compressed video stream. The events (A, B and C) represented by the VLC codewords may correspond to selected coding modes used in the video coding, selected filters, or other selected events that define how the video stream is encoded and decoded.

An adaptation scheme called “fast adaptation” in the following description is currently used in HM and is further described herein in the context of entropy encoding unit 46. According to the fast adaptation scheme, entropy encoding unit 46 may initially receive a quantized transform coefficient from quantization unit 40. An event used by entropy encoding unit 46 may represent the coefficient occurrence. Consequently, when entropy encoding unit 46 receives a coefficient, the event corresponding to the coefficient occurrence may be said to have “occurred.”

In fast adaptation, entropy encoding unit 46 may, upon determining a current event has occurred, switch the codeword mapped to the current event and the codeword mapped to a lower-ordered event immediately preceding the current event (“lower-ordered”) in the VLC table. Thus, in one example, entropy encoding unit 46 may map the current event to the codeword previously mapped to the lower-ordered event. Entropy encoding unit 46 may also map the lower-ordered event to the codeword previously mapped to the current event. Fast adaptation may, therefore, include a technique wherein upon determining an occurrence of an event of a higher-ordered codeword, entropy coding unit 46, may reassign the event associated with the higher-ordered codeword to the preceding lower-ordered codeword and the event previously associated with the lower-ordered codeword may be reassigned to the higher-ordered codeword. In some examples, if the codeword mapped to the current event is already the first or lowest-ordered codeword in the VLC table, no switching may be required.

Table 1 illustrates an example of the fast adaptation scheme. For example, as shown in Table 1, entropy encoding unit 46 may initially use a VLC table with three codewords, (1, 01, and 001) to represent three events (A, B and C). The order of the codewords is defined as the order of codewords in the VLC table.

TABLE 1

| Codeword | Order | Event |
|---|---|---|
| 1 | 0 | A |
| 01 | 1 | B |
| 001 | 2 | C |

In one example, if an event C occurs, the codeword 001 may be sent from video encoder 20 of FIG. 1 to video decoder 30 of FIG. 3. In response to coding event C using fast adaptation, entropy encoding unit 46 may switch the codeword mappings of event B and event C in Table 1. As a result, codeword 01 may represent event C and codeword 001 may represent event B. If another event C occurs, video encoder 20 may send codeword 01 to video decoder 30. Applying fast adaptation, video encoder 20 may map event C to codeword 1 and event A to codeword 01, with result shown in Table 2.

TABLE 2

| Codeword | Order | Event |
|---|---|---|
| 1 | 0 | C |
| 01 | 1 | A |
| 001 | 2 | B |

The fast adaptation scheme, in some examples, may provide high performance adaptation. However, if occurrences of different events are highly interleaved, the fast adaptation scheme may result in frequent codeword re-assignment. In addition, the assigned codewords may not adequately reflect correct event occurrence statistics, and as a result, coding efficiency may suffer. For example, coding efficiency may suffer when the VLC table includes only a few events.

Entropy encoding unit 46 may, in some examples, implement an adaptation scheme referred to as “counter based adaptation.” In counter based adaptation, entropy encoding unit 46 may assign a counter to one or more events associated with a VLC table. Entropy encoding unit 46 may use each counter to track the occurrence of the associated one or more events. For example, entropy encoding unit 46 may use a counter to track the number of occurrences of a quantized transform coefficient value received by entropy encoding unit 46. In some examples, entropy encoding unit 46 may initialize counters such that a counter associated with a lower order codeword has a larger initial value than a counter associated with a higher order codeword in a VLC table. During encoding and decoding, whenever an event is coded or decoded, an associated event counter is also incremented. In one example of counter adaptation, when a counter associated with a higher order codeword having a larger value than a counter associated a lower order codeword, entropy encoding unit 46 may perform codeword re-assignment of the events associated with the codewords. Thus, in counter-based adaptation, entropy encoding unit 46 may map events associated with larger counter values to lower ordered codewords and events associated with smaller counter values to higher order codewords. In some examples, lower ordered codewords may be shorter than or of the same length as higher ordered codewords.

Unlike fast adaptation scheme where re-mapping of codewords occurs whenever an event associated with a higher-ordered codeword that has a preceding lower-ordered codeword is coded, in counter based adaptation scheme the value of the counter associated with the higher-ordered codeword is additionally checked and re-mapping of codewords is only performed if the counter has a value larger than that of the counter preceding it.

It should be noted that depending on design, the case of a newly incremented counter having a value equal to the counter preceding it may be handled differently. In the description above, it is handled the same as the case when an newly incremented counter has a value smaller than the counter preceding it. However, in some other examples, it may be handled the same as the case when a newly incremented counter has a value larger than the counter preceding it and as a result re-mapping of codewords may be performed in that case. No matter how such case is handled, the techniques described in the present disclosure are applicable and the spirit of the invention is unchanged.

Table 3 shows one example of counter-based adaptation. At a certain instant, both counters associated with events B and C, respectively, store a value of 10.

TABLE 3

| Codeword | Order | Counter | Event |
|---|---|---|---|
| 1 | 0 | 12 | A |
| 01 | 1 | 8 | B |
| 001 | 2 | 8 | C |

If an event C occurs, video encoder 20 may send codeword 001 to video decoder 30. Entropy encoding unit 46 may also increase the counter of event C to 9. With codeword re-assignment, entropy encoding unit 46 may map codeword 01 to event C and codeword 001 to event B. The result is shown in the following Table 4.

TABLE 4

| Codeword | Order | Counter | Event |
|---|---|---|---|
| 1 | 0 | 12 | A |
| 01 | 1 | 9 | C |
| 001 | 2 | 8 | B |

If another event C occurs, video encoder 20 may send codeword 01 video decoder 30. As shown in Table 5, entropy encoding unit 46 increments the counter of event C to 10. In some examples, because event C is less than the counter of event A, entropy encoding unit 46 may not perform codeword re-assignment. Thus, as shown in Table 5, the VLC table is unchanged and only counter values are updated.

TABLE 5

| Codeword | Order | Counter | Event |
|---|---|---|---|
| 1 | 0 | 12 | A |
| 01 | 1 | 110 | C |
| 001 | 2 | 8 | B |

Codeword assignment based on a counter based adaption scheme may more accurately reflect event occurrence statistics relative to the fast adaption scheme described herein. However, counters may impose resource overhead. For example, as the number of counters increases, additional memory is required.

Both fast adaptation and counter-based adaptation schemes have advantages and disadvantages. Consequently, the two schemes may be selectively and automatically applied by entropy encoding unit 46 to maximize the advantages of each scheme. In such examples, different adaptation schemes may be applied to a VLC table at a given time based on a set of current conditions.

For example, entropy encoding unit 46 may include a VLC table that includes codewords assigned to events that represent quantized transform coefficients. When the VLC table used by entropy encoding unit 46 includes a large number of codewords and associated events, the fast adaptation scheme may provide good enough performance compared with counter based adaptation scheme. On the other hand, video encoder 20 may use counter based adaptation to more accurately assign codewords to events based on event occurrence statistics. In some examples, a VLC table that includes a small number of codewords and associated events may require a corresponding small number of counters that may not be a big resource overhead. Consequently, counter based adaptation may be more suitable than fast adaptation for small VLC tables and/or when accurate assignment of codewords to events is required.

In some examples of the present disclosure, different adaptation schemes may be applied in coding syntaxes based on the length or number of codewords in a VLC table. For example, as shown in FIG. 2, prediction unit 33 may generate syntax elements representing inter prediction coding modes and intra prediction coding modes. Codewords in a VLC table used by prediction unit 33 may correspond to different syntax elements generated by prediction unit 33. If the VLC table contains more codewords than a certain number or threshold, e.g. N, prediction unit 33 may apply a fast adaptation scheme to the VLC table. If, alternatively, the VLC table includes a number of codewords that is less than or equal to a threshold N, prediction unit 33 may apply counter based adaptation to the VLC table. The aforementioned techniques may, for example, be similarly applied to VLC tables used by entropy encoding unit 46 to code quantized transform coefficients.

In some examples, a value of threshold N may be fixed. In other examples, the value of threshold N need not be fixed. For example, a threshold may be determined based on the VLC codeword structure, such as unary codes or Golomb codes. A threshold could also be based on other factors, including but not limited to QP (quality parameter), slice type, memory size requirement, etc. Example techniques are further described herein.

FIG. 4 is a flow diagram illustrating an example method to select and apply Variable Length Coding (VLC) techniques based the number of codewords in a VLC table, in accordance with one or more aspects of the present disclosure. Although the example method of FIG. 4 is illustrated using entropy encoding unit 46, the example technique may be similarly applied by entropy decoding unit 70. In the example of FIG. 4, entropy encoding unit 46 may use a VLC table to map codewords to events. Each event may correspond to a quantized transform coefficient received from quantization unit 40. As shown in FIG. 4, entropy encoding unit 46 may determine if a number of codewords stored in a VLC table satisfies a threshold (100).

In one example, a number of codewords may refer to a quantity of codewords in the VLC table. A quantity of codewords may correspond to a quantity of all the codewords or a quantity of a subset of codewords. In one example, entropy encoding unit 46 may determine an index of at least one of the codewords in the codeword table and further determine if the index satisfies the threshold. An index may correspond to a position of a codeword in a codetable. For example, an index of zero may correspond to a lowest ordered codeword in a codeword table. In this way, the index of a codeword may be used to determine a number of codewords in a table. For example, if entropy encoding unit 46 determines a codeword having an index of 5, entropy encoding unit 46 may determine six codewords exist in the codeword table. Entropy encoding unit 46 may compare index 5 to a threshold. Other techniques may also be used to determine a number of codewords in a codeword table. For example, a function executable by encoding unit 46 may take an input value indicating a number of codewords and may return a Boolean value indicating whether the codeword table includes a number of codewords at least equal to the input value. In general, any suitable technique for determining a number of codewords may be used. In some examples, a threshold may be a constant value. For example, the threshold value may initially be specified by a user and stored by video encoder 20, e.g., in entropy encoding unit 46. Video decoder 30 may similarly store the threshold value. In some examples, the threshold may be calculated using techniques described herein.

Entropy encoding unit 46 may in some examples compare the threshold to the quantity of codewords stored in the VLC table to determine whether the number of codewords satisfies the threshold. For example, video encoder 20 may select a codeword adaptation scheme from a group of two or more codeword adaptation schemes based on whether the number of codewords satisfies the threshold (102). In some examples, satisfying a threshold may indicate the number of codewords is greater than the threshold. In other examples, satisfying a threshold may indicate the number of codewords is less than the threshold. In still other examples, satisfying a threshold may indicate the number of codewords is equal to a threshold. In any event, entropy encoding unit 46 may include logic to apply fast adaptation and counter based adaptation schemes to the VLC table. Entropy encoding unit 46 may also include logic to apply other adaptation schemes in addition to fast adaptation and counter based adaptation. Thus, in some examples, entropy encoding unit 46 may select an adaptation scheme based on the whether the number of codewords satisfies the threshold. As shown in FIG. 4, entropy encoding unit 46 may apply the selected adaptation scheme to the codewords stored in the VLC table (114).

As shown in FIG. 4, entropy encoding unit 46 may, in some examples, determine the number of codewords in a VLC table (104). When entropy encoding unit 46 determines that the number of codewords in the VLC table is greater than the threshold (106), entropy encoding unit 46 may select a fast adaptation scheme (108). In other examples, when entropy encoding unit 46 determines that the number of codewords in the VLC table is less than the threshold (110), entropy encoding unit 46 may select a counter based adaptation scheme (112). In either case, upon selecting a codeword adaptation scheme, entropy encoding unit 46 may apply the selected codeword adaptation scheme to the codewords stored in the VLC table (114).

As previously discussed, in some examples, entropy encoding unit 46 may calculate a threshold using various techniques. In one example technique, entropy encoding unit 46 may select one or more codewords in the VLC table, and then generate the threshold based on the selected codewords. For instance, entropy encoding unit 46 may determine a codeword type of each selected codeword. Stated another way, the value of the threshold may be a function of the codeword types. Examples of codeword types may include a fixed-length coding type, a Huffman coding type, a Golomb coding type, or a Unary coding type. More generally a codeword type may refer to a codeword associated with a common generation scheme. Entropy encoding unit 46 may generate a threshold based on one or more codeword types of the selected codewords. Thus, in some examples, entropy encoding unit 46 may determine that whether fast adaptation or counter based adaptation provide superior performance for codewords of a particular codeword type or combination of codeword types. In such examples, the threshold may be generated based on the codeword type to provide improved performance.

In some examples, a video decoder, e.g., video decoder 30 as shown in FIG. 1, may also perform one or more codeword adaptation schemes of the present disclosure as previously described with respect to entropy encoding unit 46. For example, video encoder 20 of FIG. 2 may encode video data according to fast adaptation and/or counter-based adaptation schemes. In one example, video encoder 20 may generate a bitstream that includes the encoded video data, which video decoder 30 may later decode. The bitstream, may in some examples, include one or more codewords stored in a VLC table associated with events of video encoder 20. Video decoder 30 may further include VLC tables that include codeword-to-event mappings corresponding to codeword-to-event mappings of VLC tables included in video encoder 20. Video decoder 30 may, in some examples, receive the bitstream and decode the encoded video data.

Video decoder 30 may receive a bitstream that includes a codeword. Video decoder 30 in some examples may be a video decoder 90 as shown in FIG. 3. Video decoder 90 may further include, as described above, an entropy decoding unit 70. Entropy decoding unit 70 may initially receive codewords included the bitstream received from video encoder 20. Entropy decoding unit 70 may include VLC tables that are similar or equal to VLC tables of entropy encoding unit 46. Each codeword in the VLC table used by entropy decoding unit 70 may correspond to an event that represents certain syntax element such as a quantized transform coefficient. In this way, entropy decoding unit 70 may receive a codeword and identify a corresponding event that represents the coded, quantized transform coefficient.

In one example, entropy decoding unit 70 may initially receive a codeword included in a bitstream. The received codeword may correspond to a codeword stored in a VLC table used by entropy encoding unit 46. Furthermore, the codeword may be associated with an event of entropy coding unit 46. Entropy decoding unit 70 may identify a codeword from the bitstream matching one in the VLC table used by entropy decoding unit 70. Entropy decoding unit 70 may further identify an event associated with the matching codeword. In some examples, responsive to identifying the event associated with the matching codeword, e.g., determining the event has been coded by entropy encoding unit 46, entropy decoding unit 70 may perform one or more codeword adaptation schemes described in the present disclosure. In this way, the codeword-to-event mappings of the VLC table of entropy decoding unit 70 may be synchronized with the codeword-to-event mappings of the VLC table of entropy encoding unit 46. In some examples, data indicating the codeword adaptation schemes applied to VLC tables of entropy encoding unit 46 may be sent by video encoder 20 to video decoder 30. In this way, entropy decoding unit 70 may apply the codeword adaptation schemes in the manner indicated by entropy encoding unit 46. Techniques described in examples of FIGS. 4-10 may use similar methods to synchronize codeword-to-event mappings between video encoder 20 and video decoder 30.

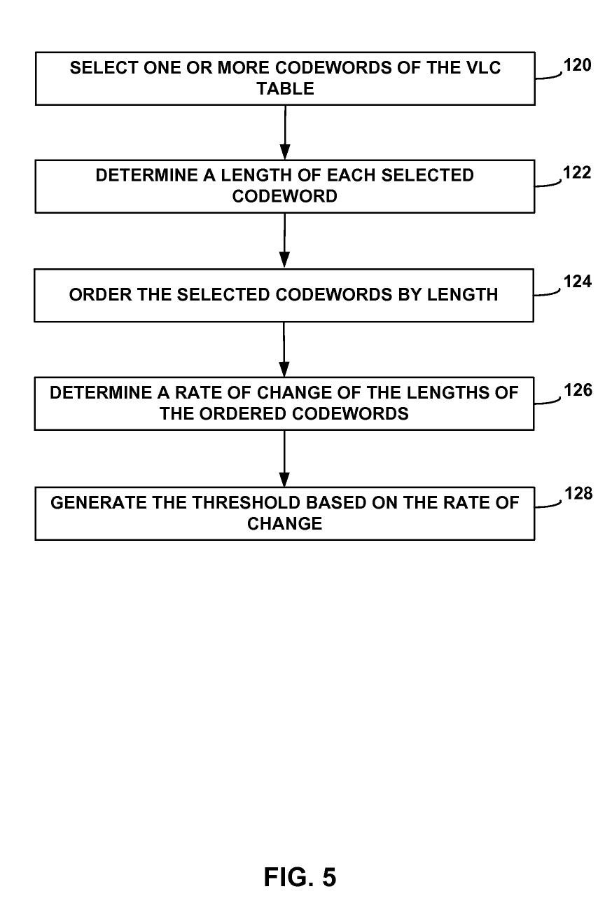

In some examples, entropy encoding unit 46 may calculate a threshold based on the lengths of codewords in a VLC table. FIG. 5 is a flow diagram illustrating an example method to generate a threshold based on the lengths of codewords in a VLC table, in accordance with one or more aspects of the present disclosure. Although the example method of FIG. 5 is illustrated using entropy encoding unit 46, the example technique may be similarly applied using entropy decoding unit 70. As shown in FIG. 5, entropy encoding unit 46 may initially select one or more codewords of the VLC table (120). As described in previous examples, codewords in the VLC table may be mapped to events that each represents certain syntax element such as quantized transform coefficients. Entropy encoding unit 46 may determine a length of each selected codeword (122). In some examples, a codeword may comprise a quantity of bits. Consequently, a length of a selected codeword may comprise the quantity of bits to that represent the selected codeword. For example, a codeword 01 may indicate a quantity of bits equal to 2. A codeword 001 may indicate a quantity of bits equal to 3.

As shown in FIG. 5, entropy encoding unit 46 may order the selected one or more codewords by length from a shortest codeword having a shortest length to a longest codeword having a longest length (124). For example, a VLC table may include the codewords 1, 01, and 001. To order the selected codewords by length from a shortest length to a longest length, entropy encoding unit 46 may order the selected codewords as 1, 01, and 001, corresponding to codeword lengths of 1, 2, and 3.

In some examples, entropy encoding unit 46 may determine a rate of change of the length of each ordered codeword (126). For example, the rate of change of the lengths of ordered codewords 1, 001, and 00001 may be equal to 2. The rate of change may be calculated by determining a difference between a first length of a first codeword and a second length of a second codeword. In the current example, codeword 001 may have a length of 3 and codeword 00001 may have a length of 5. The difference in length may be equal to 5−3=2. In other examples, a rate of change equal to an average rate of change may be calculated for two or more ordered codewords. For example, an ordered group of codewords may include 1, 01, and 0000001. A first rate of change between codeword 1 and 01 may be equal to 1. A second rate of change between 01 and 0000001 may be 5. Consequently, an average rate of change of the lengths of the codewords may be equal to (5+1)/2=3. More generally, any rate of change function, may be used to calculate one or more rates of change of the lengths of ordered codewords.

As shown in FIG. 5, entropy encoding unit 46 may generate the threshold based on the rate of change of the lengths of the ordered codewords (128). For example, fast adaptation schemes may be more suitable for rates of change in a first range of rates of change. In other examples, counter based adaptation schemes may be suitable for rates of change in a second range of rates of changes. In such examples, entropy encoding unit 46 may generate a threshold based on the rate of change of the lengths of the ordered codewords in order to select a suitable adaptation scheme. In some examples, if the length of codewords increases at a high rate with the order of the codewords, entropy encoding unit 46 may generate a large threshold such that counter-based adaptation is applied to a greater number of lower-ordered codewords. In other examples, if the lengths of codewords increase at a low rate, entropy encoding unit 46 may generate a small value threshold.

In some examples, entropy encoding unit 46 may generate a threshold based on a characteristic that describes one or more codewords of a VLC table. For example, entropy encoding unit 46 may initially select one or more codewords of a VLC table. Entropy encoding unit 46 may determine an operation that generates a characteristic based on a property of each of the selected codewords. A property of a selected codeword may include a length of a codeword; a pattern or arrangement of values, e.g., bits, which comprise the codeword; or any other information that describes the codeword. In some examples, a characteristic may include a descriptive statistics such as a variance, mean, median, or standard deviation. In one example, entropy encoding unit 46 may select one or more codewords of a VLC table. Entropy encoding unit 46 may execute an operation that generates a median codeword length based on a length, e.g., property, of each selected codeword. The median codeword length may be a characteristic of the selected codewords. Entropy encoding unit 46 may use the median codeword length, in some examples, to generate the threshold. In some examples, entropy encoding unit 46 may use the threshold based on the characteristic order to select a suitable adaptation scheme.

In another example, the threshold may be a variance function of the length of the codewords. A selected function, e.g., variance, can be a fixed function known to both the encoder and the decoder, or can be transmitted to the decoder in PPS or SPS, or can be derived based on side information like picture size, block size, prediction mode (Inter, Intra), partition mode (2N×2N, N×2N . . . ), etc. In such examples, an encoder and decoder can derive the value of the threshold based on codeword length variance.

For instance, prediction unit 33 may, in some examples, generate a threshold based on syntax information including syntax elements that describe characteristics and/or processing of macroblocks and other coded units of encoded video data. The threshold may be determined based on side information, e.g., partition mode. The side information can be the available side information of the current block, or can be the side information from already encoded/decoded blocks. For example, prediction unit 33, in some examples, may generate syntax elements that define a context used to encode video data. Prediction unit 33 may generate a threshold based on the syntax information. In some examples, syntax information may include a picture size of a picture that includes video data encoded as the encoded video data. In some examples, syntax information may include a picture type of the picture that includes video data encoded as the encoded video data. Syntax information may include a block size associated with the encoded video data.

In some examples, syntax information may include a prediction mode that indicates an encoding technique used to encode the encoded video data. In other examples, syntax information may include a partition mode that indicates a quantity one or more video blocks included in a partition of the picture. In some examples, syntax information may include a quantization parameter usable by quantization unit 40 to quantize one or more coefficient values that represent one or more pixels of a block encoded as encoded video data. In some examples, syntax information may include a motion vector value generated by prediction unit 33 that comprises a displacement of a predicted block relative to a video block encoded in the encoded video data.

Syntax information in other examples may include a motion vector prediction value that comprises a predicted displacement of the predicted block relative to the video block. In some examples, syntax information may include a quality parameter that indicates a performance characteristic of a communication channel that transmits the encoded video data. In other examples, syntax information may include a slice type that indicates a prediction mode applied to encoded video data. In still other examples, a threshold may be based on a memory size requirement that indicates a quantity of memory required to encode the encoded video data.

Video encoder 20 may in some examples, send a threshold to a receiver such as a video decoder 30. In some examples, entropy encoding unit 46 of video encoder 20 may initially generate a threshold using techniques described herein. Video encoder 20 may generate a bit stream, e.g., including encoded video data that is capable of storing the threshold. In some examples, video encoder 20 may store the threshold in the bitstream. Video encoder 20 may send the bitstream to video decoder 30 which may be capable of applying a suitable adaptation scheme to codewords stored in a variable length coding table of the receiver based on the threshold. In some examples, the bitstream may include a parameter set. The parameter set may include one or more parameters that specify coding information associated with the bitstream. Video encoder 20 may store the threshold in the parameter set. For example, the threshold may be transmitted in PPS (picture parameter set) or SPS (slice parameter set).

As discussed herein, codeword adaptation schemes may include fast adaptation and counter based adaptation. Video encoder 20 may additionally perform a codeword adaptation scheme referred to as “modified counter based adaptation.” In one example, entropy encoding unit 46 may apply the modified counter based adaptation scheme to VLC tables that include mappings of codewords to events that represent certain syntax element such as quantized transform coefficients.

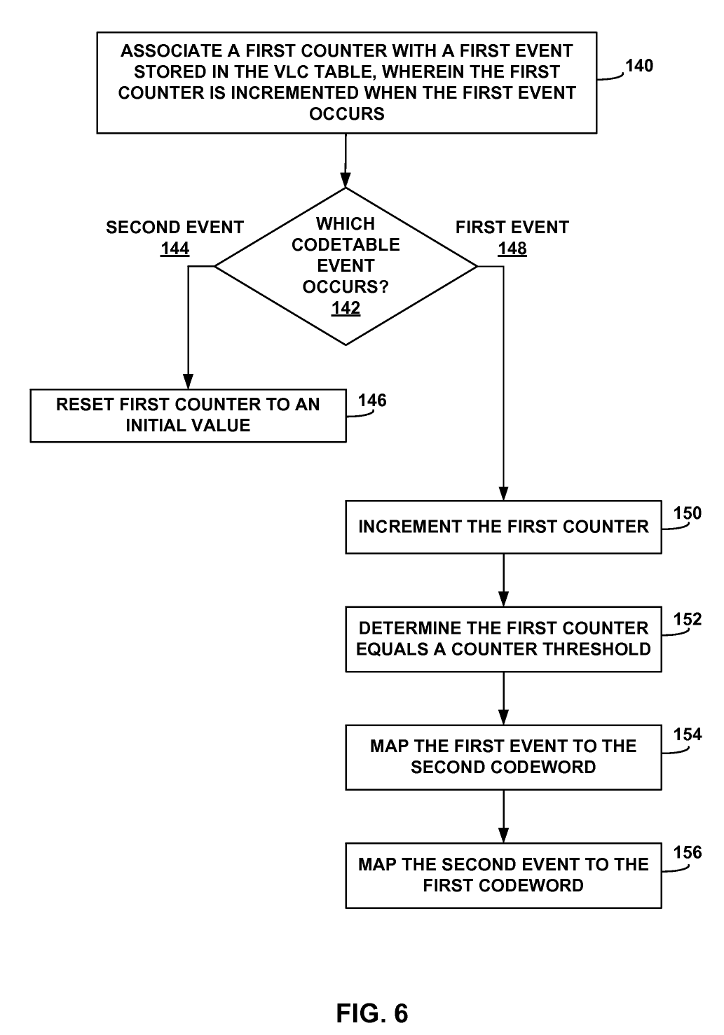

FIG. 6 is a flow diagram illustrating an example method to perform modified counter based adaptation on a VLC table, in accordance with one or more aspects of the present disclosure. Although the example method of FIG. 6 is illustrated using entropy encoding unit 46, the example technique may be similarly applied using entropy decoding unit 70. In modified counter based adaptation, a counter may be associated with an event. The counter may be used to record a quantity of consecutive occurrences of the event. A quantity of consecutive occurrences may refer to the number of times the event is coded without a different event occurring, e.g., the number of times a quantized transform coefficient is received by entropy coding unit 46 for entropy coding.

In the modified counter based adaptation scheme, if a counter value becomes greater than or equals a threshold value, entropy encoding unit 46 may map the current event associated with the counter to a lower ordered codeword. For example, entropy encoding unit 46 may map the current event associated with the counter to a lower ordered codeword of an event that immediately precedes the current event. The event previously mapped to the lower ordered codeword may be mapped by entropy encoding unit 46 to the codeword previously associated with the current event. Stated another way, if the counter value becomes greater than or equals the threshold value using modified counter based adaptation, entropy encoding unit 46 may perform codeword reassignment as described herein for counter based adaptation. In modified counter based adaptation, however, if a different event occurs before the counter of the current event reaches the threshold, entropy encoding unit 46 may reset the current counter to 0.

As shown in FIG. 6, entropy encoding unit 46 may associate a first counter with a first event stored in a VLC table such that the first event is mapped to a first codeword (140). The first event may represent a quantized transform coefficient. The first counter may be incremented each time the first event is coded, e.g., “occurs.” The VLC table may further include a second event mapped to a second codeword. In some examples, the second code word may be a lower ordered codeword than the first codeword. Entropy encoding unit 46 may determine which event occurs when an event is coded (142). When the second event is coded (144), entropy encoding unit 46 may reset the first counter to an initial value (146). In some examples, an initial value may be zero. When the first event is coded (148), entropy encoding unit 46, using modified counter based adaptation, may increment the first counter (150). Entropy encoding unit 46 may further determine the first counter equals a counter threshold (152). Responsive to determining the first counter equals the counter threshold, entropy encoding unit 46 may map the first event to the second codeword (154). Entropy encoding unit 46 may also map the second event to the first codeword (156). In this way, video encode 20, using modified counter based adaptation, may perform codeword reassignment when the first counter equals a counter threshold.

In one example of modified counter based adaptation, three events A, B, and C may be mapped to codewords 1, 01, and 001 respectively. Counters may further be associated with events A, B, and C, having values 0, 0, 0 respectively. A counter threshold may be a value of 3. In the current example, the following event sequence may occur: B, B, B, C, A. The initial sequence of B, B, B may cause entropy encoding unit 46 to increase the counter associated with B to a value of 3. Consequently, because the counter associated with B is equal to the counter threshold of 3, entropy encoding unit 46 may map B to codeword 1 and A to codeword 01. Because A is subsequently coded in the sequence, entropy encoding unit 46 may reset the counter associated with B to zero and the counter of A may be incremented to 1. Later, when event C occurs, entropy encoding unit 46 may reset the counter of A to zero and increment the counter of C to 1. After coding the events B, B, B, C, A, the VLC table may indicate event codeword mappings of B to 1, A to 01, and C to 001. Counter values of events B, A, C may be 0, 0, 1 respectively.

According to another example of this disclosure, different adaptation schemes may be applied to different events in the same VLC table based on the ordering of the codewords and events in the table. In some examples, accurate mapping of events to lower ordered codewords in a VLC table may substantially affect coding efficiency. The lower-ordered codewords may be associated with more frequently coded events and therefore accurate mapping of lower-ordered codewords to events may improve coding efficiencies. Thus, in some examples, counter based adaptation may be applied to a first group of lower-ordered codewords and associated events, while fast adaptation may be applied to the remaining codewords and associated events of a VLC table.

In one example, a threshold value M may be defined such that the M events that are associated with the M lowest order codewords in a VLC table are tracked and each of the codewords may be adjusted based on counter based adaptation. The remainder of the events in the VLC table may be handled using fast adaptation. The value of M may be determined based on the VLC codeword structure, such as unary codes or Golomb codes. The value of M could also be based on other factors, including but not limited to, QP (quality parameter), slice type, memory size requirement, etc. Additional techniques for generating a threshold are described herein.

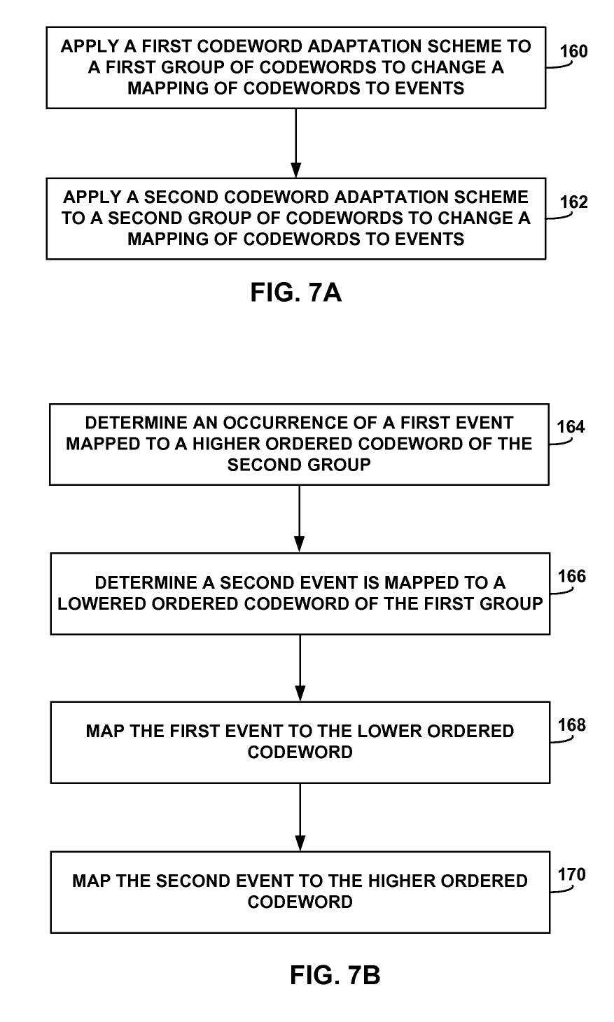

FIG. 7A is a flow diagram illustrating an example method to apply different adaptation schemes to different events in the same VLC table based on the ordering of the codewords and associated events in the table, in accordance with one or more aspects of the present disclosure. Although the example method of FIG. 7A is illustrated using entropy encoding unit 46, the example technique may be similarly applied using entropy decoding unit 70. As in previous examples, the technique of FIG. 7A may be used by entropy encoding unit 46. Entropy encoding unit 46 may, for example, use a VLC table that includes codewords mapped to events. Each event may represent a certain syntax element such as quantized transform coefficient. As shown in FIG. 7A, entropy encoding unit 46 may apply a first codeword adaptation scheme to a first group of codewords of a VLC table to change a mapping of codewords to events in the VLC table (160). Entropy encoding unit 46 may apply a second codeword adaptation scheme to a second group of codewords in the VLC table to change the mapping of the codewords to the events in the VLC table (162).

In the current example, the first codeword adaptation scheme may be a fast adaptation scheme and the second codeword adaptation scheme may be a counter-based adaptation scheme. In other examples, the first codeword adaptation scheme may be a counter-based adaptation scheme and the second codeword adaptation scheme may be a fast adaptation scheme. In still other examples, a codeword adaptation scheme may be a modified code-table adaptation scheme as described herein. In some examples, the first group of codewords of the VLC table may include a quantity of codewords equal to a threshold. A threshold may be a constant value or may be generated according to techniques described herein.

In some examples, the first group of codewords as described in FIG. 7A may include lower ordered codewords in the VLC table. The second group of codewords as described in FIG. 7A may include higher ordered codewords in the VLC table. In some examples, entropy encoding unit 46 may map lower ordered codewords to a first group of events in the VLC table that occur with greater frequency than a second group of events in the VLC table mapped to the higher ordered codewords. Thus, in some examples, lower ordered codewords may be represented using fewer bits than higher ordered codeword. For example, a lowered ordered codeword 01 may require fewer bits to represent an event than a higher ordered codeword 11101. In this way, more frequently occurring events may be mapped to lower ordered codewords and consequently, greater coding performance may be realized by mapping codewords with less bits to more frequently occurring events.

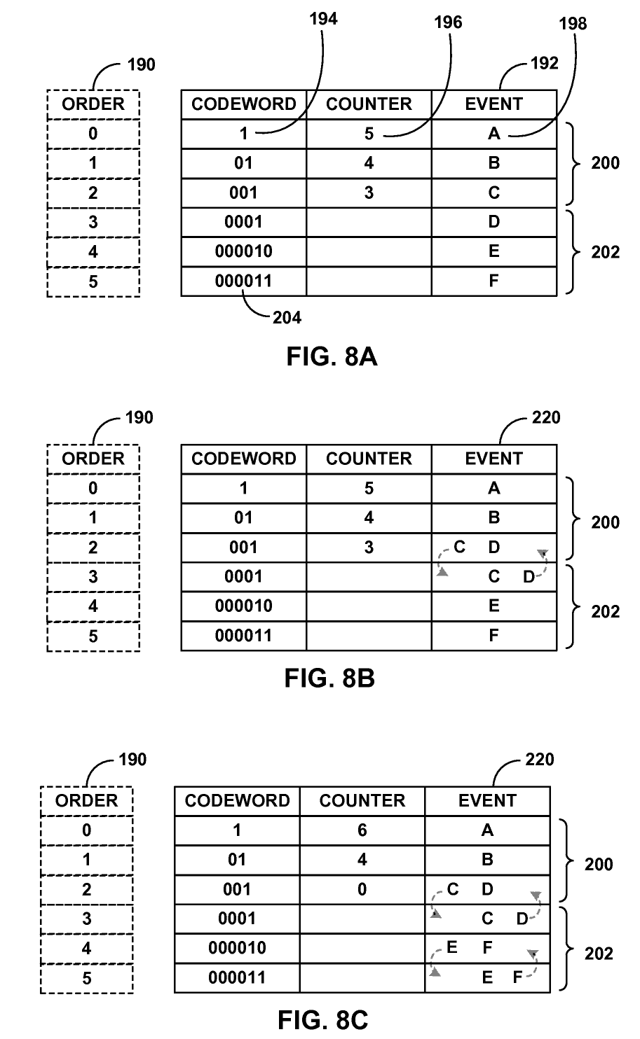

FIG. 7B is a flow diagram illustrating an example method to map a first event associated with a higher-ordered codeword of a second group to a lower-ordered codeword of a first group, in accordance with one or more aspects of the present disclosure. As shown in FIG. 7B, entropy encoding unit 46 may determine an occurrence of a first event, wherein the first event is mapped to higher ordered codeword in a group of higher ordered codewords of a VLC table (164). Entropy encoding unit 46 may further determine a second event that is mapped to a lower ordered codeword of a group of lower ordered codewords in the VLC table (166). Responsive to the occurrence of the first event, entropy encoding unit 46 may map the first event to the lower ordered codeword (168). Entropy encoding unit 46 may also map the second event to the higher ordered codeword (170). In the current example, the higher ordered codeword may include a lowest ordered codeword of the higher ordered codewords. The lower ordered codeword, in the current example, may include a highest ordered codeword of the lower ordered codewords. Thus, as shown in the method of FIG. 7B, entropy encoding unit 46 may perform codeword reassignment of events between different groups based on different adaptation schemes that may be applied to different groups. The techniques of FIGS. 7A and 7B are further illustrated in FIGS. 8A and 8B.

FIGS. 8A, 8B, 8B are diagrams illustrating example VLC tables, in accordance with one or more aspects of the present disclosure. Although the examples of FIG. 8 are illustrated using entropy encoding unit 46, the example techniques may be similarly applied using entropy decoding unit 70. FIG. 8A illustrates a VLC table 192 that includes events associated with codewords and counters associated with events. VLC table 192 may be used by entropy encoding unit 46 to entropy code quantized transform coefficients. For example, as shown in FIG. 8, event 198 may be associated with codeword 194. Furthermore, counter 196 may be associated with event 198. Event 198 may, e.g., be referred to as Event A. Codeword 194 may be referred to as codeword 1. FIG. 8A further illustrates an order table 190. Order table 190 may not be included in entropy encoding unit 46 in some examples, and may be shown in FIG. 8A for purposes of illustrating lower-ordered and higher-ordered codewords. For example, codeword 194 may be a lowest ordered codeword having an order of 0. Codeword 204 may be a highest ordered codeword having an order of 5.

As shown in FIG. 8A, entropy encoding unit 46 may apply counter based adaptation to lower ordered codewords 1, 01, 001 of codeword group 200. Entropy encoding unit 46 may apply fast adaptation to higher ordered codewords 0001, 000010, 000011 of codeword group 202. In this way, entropy encoding unit 46 may apply different adaptation schemes to different groups of codewords.

In one example, counter-based and fast adaptations are handled separately and independently. In such an example, counter based adaptation is applied to codeword group 200 and fast adaptation is applied to codeword group 202. In the current example, events of group 202 mapped using fast adaptation may not be mapped to codewords of group 200 mapped using counter based adaptation, and vice versa.

In a different example, the two different adaptations may be jointly applied by entropy encoding unit 46. When jointly applying adaptations, an event originally mapped with fast adaptation may be mapped by entropy encoding unit 46 to a codeword handled with counter based adaptation, and vice versa. For example, as shown in FIG. 8B, entropy encoding unit 46 may apply counter based adaptation to codeword group 200 and fast adaptation to codeword group 202. When event D, having a lowest order codeword for fast adaptation is coded, entropy encoding unit 46 may map Event D to the highest order codeword 001 of codeword group 200 to which video encoder 20 applies counter based adaptation. Event C, originally mapped to the highest order codeword 001 of codeword group 200, may be mapped by entropy encoding unit 46 to the lowest order codeword 0001 of codeword group 202 to which video encoder 20 applies fast adaptation. Entropy encoding unit may leave the associated counter value to event D in FIG. 8B unchanged.

In another example as shown in FIG. 8C, the following event sequence may be coded: D, A, F. Responsive to determining event D has occurred, entropy encoding unit 46, applying fast adaptation to codeword group 202, may map event D to codeword 001 and may further map event C to codeword 0001. Because entropy encoding unit 46 maps event D to codeword 001 of group 200, entropy encoding unit 46 may assign a counter to event D with an initial value. As shown in FIG. 8B, the initial value of the counter associated with event D is equal to 0. When entropy encoding unit 46 maps event C to codeword 0001 of group 202, entropy encoding unit 46 may not associate a counter with codeword 0001 because entropy encoding unit 46 applies fast adaptation to codewords of group 202.

Continuing with the current example, entropy encoding unit 46 may, responsive to determining event A has occurred, increment the counter associated with counter A to 6. Entropy encoding unit 46 may increment the counter associated with counter A because counter based adaptation is applied to codeword group 200. Entropy encoding unit 46 may, responsive to coding event F, map event F to codeword 000010 in accordance with fast adaptation applied to codeword group 202. Entropy encoding unit 46 may also map event E to codeword 000011 to complete the codeword reassignment associated with fast adaptation. VLC mapping table 220 illustrates mappings of events to codewords after encoding sequence D, A, F. In this way, FIGS. 8A and 8B illustrate entropy encoding unit 46 applying different adaptation schemes to different groups of codewords.

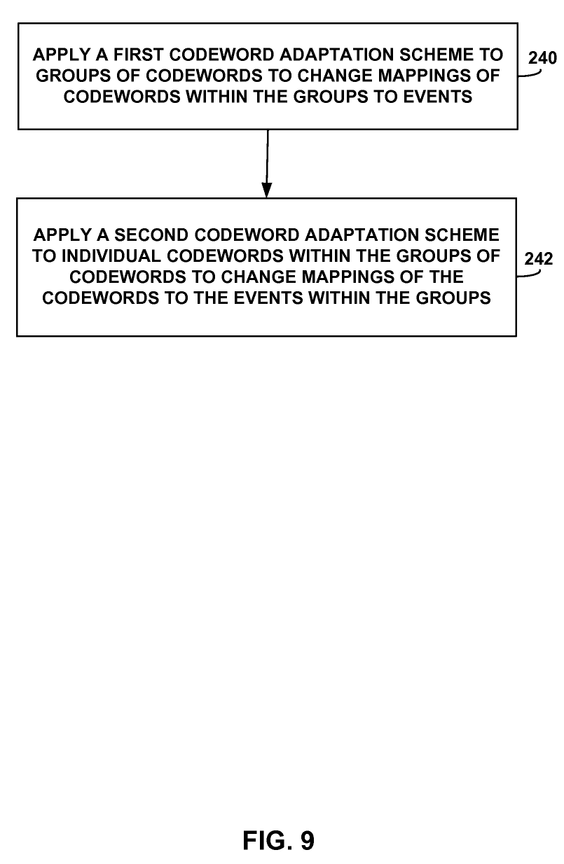

FIG. 9 is a flowchart illustrating a method to apply a first codeword adaptation scheme to groups of codewords and applying a second codeword adaptation scheme to individual codewords within the groups of codewords, in accordance with one or more aspects of the present disclosure. Although the example method of FIG. 9 is illustrated using entropy encoding unit 46, the example technique may be similarly applied using entropy decoding unit 70. As shown in FIG. 9, entropy encoding unit 46 may apply a first codeword adaptation scheme to groups of codewords in a VLC table to change mappings of groups of codewords within the groups to events in the VLC table (240). Entropy encoding unit 46 may, as shown in FIG. 9, apply a second codeword adaptation scheme to individual codewords within the groups of codewords in the VLC table to change mappings of the codewords to the events within the groups in the VLC table (242).

According to some examples, all codewords in a VLC table may be divided into K groups, with each group containing N_{I}, N₂, . . . , N_{K} events. For example, a VLC table may be divided into 2 groups—Group 1 and Group 2—with each containing 3 events. Group 1 may include events mapped to lower-ordered codewords, and Group 2 may include events mapped to higher-ordered codewords. A first adaptation scheme, e.g., counter based adaptation, may be applied to events at a group level, and a second adaptation scheme, e.g., fast adaptation, may be applied to events within each group. As a result, only 2 counters are needed, one for each group. When an event in a group occurs, entropy encoding unit 46 may increment the counter for the corresponding group. Moreover, entropy encoding unit 46 may apply fast adaptation to the coded event within the group.

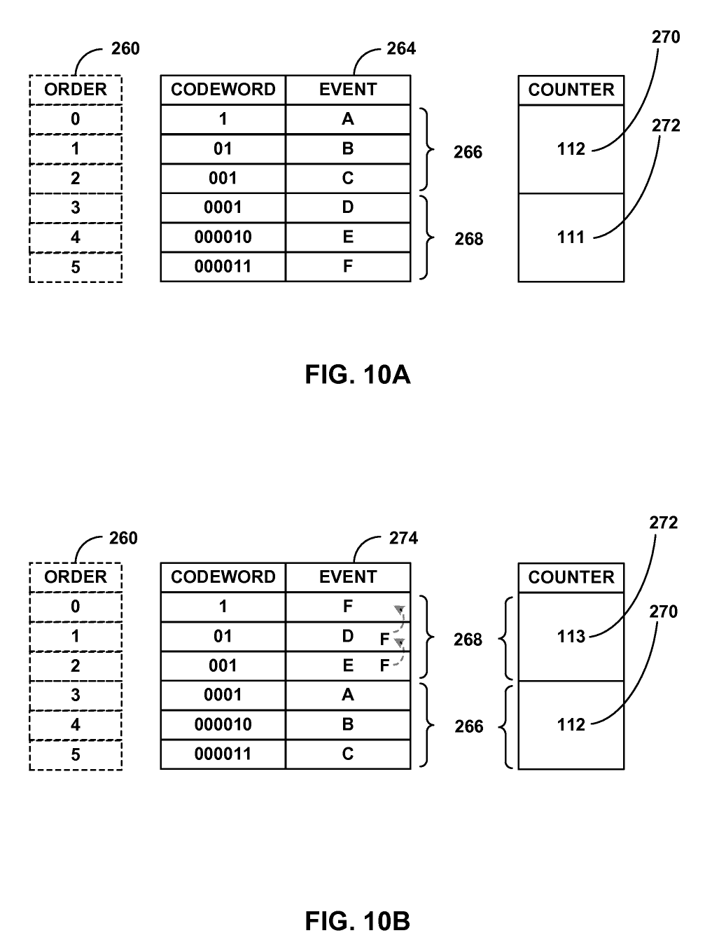

FIGS. 10A, 10B illustrate a first technique of applying multiple adaptation schemes to a codeword table, in accordance with one or more aspects of the present disclosure. Although the example methods of FIG. 10 are illustrated using entropy encoding unit 46, the example technique may be similarly applied using entropy decoding unit 70. FIG. 10A includes a codeword mapping table 264 similar to the codeword mapping table as shown in FIG. 8A. Similarly, FIG. 10A includes an order table 260 similar to the order table as shown in FIG. 8A. As shown in FIG. 10A, codeword mapping table 264 may be divided into event groups 266, 268. Entropy encoding unit 46 may apply fast adaptation to individual events within each event group. FIG. 10A further includes counters 270, 272. Counter 270 may be associated with event group 266 and counter 272 may be associated with event group 268.

As shown in FIG. 10A, when an event within the group is coded, entropy encoding unit 46 may perform fast adaptation within the group. For example, entropy encoding unit 46 may perform codeword reassignment of the coded event and the immediately preceding event. In addition to perform fast adaptation within the group, entropy encoding unit 46 may increment the counter associated with the group that includes the coded event. In some examples, when a first counter associated with a higher-ordered codewords exceeds a second counter associated with a lower-ordered codewords, entropy encoding unit 46 may perform codeword reassignments of the groups of events. The following example of FIGS. 10A, 10B illustrate one example technique of group level reassignment of events.

As shown in FIG. 10A, Events A, B, C in event group 266 are assigned to codewords 1, 01, 001. Events A, B, C are associated with lower ordered codewords as shown in FIG. 10A by order table 260. Assume that in entropy encoding unit 46 counter 270 for event group 266 has a value of 112. Entropy encoding unit 46 may perform fast adaptation to individual events within each event group and counter adaptation to each group of events. Event group 268 is associated with higher ordered codewords.

In one example technique, the event sequence: F, F may be determined by entropy encoding unit 46. In response to a first occurrence of event F, entropy encoding unit 46 may perform fast adaptation on codewords in event group 268. Consequently, entropy encoding unit 46 may perform codeword reassignment of Event E and Event F such that Event F is assigned to codeword 000010 and event E is assigned to codeword 000011. In addition, entropy encoding unit 46 may apply counter adaptation on a group level such that in response to an occurrence of Event F, entropy encoding unit 46 increments counter 272 to 112. Because counter 272 does not exceed counter 270, entropy encoding unit 46 does not perform group level codeword reassignment.

In response to a second occurrence of Event F, entropy encoding unit 46 may perform fast adaptation on codewords in event group 268. Consequently entropy encoding unit 46 may perform codeword reassignment of Event F and Event D such that Event F is assigned to codeword 0001 and Event D is assigned to codeword 000010. In addition, entropy encoding unit 46 may apply counter adaptation on a group level such that in response to an occurrence of Event F, entropy encoding unit 46 increments counter 272 to 113. Because counter 272 exceeds counter 270, entropy encoding unit 46 may reassign codewords of event group 268 to event group 266 and codewords of event group 266 to event group 268.

FIG. 10B illustrates the resulted codeword mapping table 274 after coding an event sequence F, F, based on the case shown in FIG. 10A. As shown in FIG. 10B., responsive to coding event sequent, F, F, entropy encoding unit 46 may reassign codewords to event group 266. In addition, entropy encoding unit 46 may reassign codewords to event group 268. In the current example, because codeword reassignment may occur at a group level, the order of different events within each group may remain unchanged during the group level codeword reassignment.

In a second technique, entropy encoding unit 46 may, when applying multiple adaptation schemes to a codeword table, reassign codewords at an event level. FIG. 10A may be used to illustrate one such example technique of codeword reassignment at an event level. As shown in FIG. 10A, entropy encoding unit 46 may encode an event sequence F, F. Entropy encoding unit 46 may perform two fast adaptation operations such that event F is mapped to codeword 0001, event D is mapped to codeword 000010, and event E is mapped to codeword 000011. In such an example, entropy encoding unit 46 may increment counter 272 to 113. Entropy encoding unit 46 may determine that counter 272 exceeds counter 270. As discussed above, in the current example, entropy encoding unit 46 may reassign codewords at an individual event level rather than event group level. Thus, responsive to determining that counter 272 exceeds counter 270, entropy encoding unit 46 may reassign Event F to codeword 001 and may further reassign Event C to codeword 0001. As a result, event group 266 now contains event A, B and F. Event group 268 contains event C, D and E. Entropy encoding unit 46 may also reassign counter 272 to event group 266 and may reassign counter 270 to event group 268. In this way, entropy encoding unit 46 may apply multiple adaptation schemes to a codeword such that codewords may be reassigned at an event level.

In one or more examples, the functions described may be implemented in hardware, software, firmware, or any combination thereof. If implemented in software, the functions may be stored on or transmitted over as one or more instructions or code on a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules configured for encoding and decoding, or incorporated in a combined codec. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a codec hardware unit or provided by a collection of interoperative hardware units, including one or more processors as described above, in conjunction with suitable software and/or firmware.

Various examples have been described. These and other examples are within the scope of the following claims.

What is claimed is:

1. A method comprising:
applying a first codeword adaptation scheme to a first group of codewords of a variable length coding (VLC) table to change a mapping of codewords to events in the VLC table; and
applying a second codeword adaptation scheme to a second group of codewords of the VLC table to change the mapping of the codewords to the events in the VLC table.

2. The method of claim 1, wherein the first codeword adaptation scheme comprises a fast adaptation scheme and the second codeword adaptation scheme comprises a counter-based adaptation scheme.

3. The method of claim 1,
determining the first group of codewords of the VLC table includes a quantity of codewords equal to a threshold,
wherein the first group of codewords comprises lower ordered codewords in the VLC table,
wherein the second group of codewords comprises higher ordered codewords in the VLC table, and
wherein the lower ordered codewords are mapped to a first group of events in the VLC table that occur with greater frequency than a second group of events in the VLC table mapped to the higher ordered codewords.

4. The method of claim 3, further comprising:
determining an occurrence of a first event, wherein the first event is mapped to a higher ordered codeword in the higher ordered codewords of the VLC table;
determining a second event is mapped to a lower ordered codeword in the lower ordered codewords of the VLC table;
mapping the first event to the lower ordered codeword;
mapping the second event to the higher ordered codeword.

5. The method of claim 4, further comprising:
responsive to determining the occurrence of the first event, incrementing a first counter associated with the higher ordered codeword; and
determining the first counter is greater than a second counter associated with the lower ordered codeword.

6. The method of claim 4, wherein a counter is associated with a first event, the method further comprising:
responsive to mapping the second event to the higher ordered codeword, associating the second event with the counter.

7. The method of claim 4,
wherein the higher ordered codeword comprises a lowest ordered codeword of the higher ordered codewords; and
wherein the lower ordered codeword comprises a highest ordered codeword of the lower ordered codewords.

8. The method of claim 1, further comprising:
receiving at a decoder a bitstream of encoded video data that includes at least one codeword.

9. The method of claim 1, wherein at least the first codeword adaptation scheme or the second codeword adaptation scheme comprises a modified counter-based adaptation scheme further comprising:
associating a first counter with a first event stored in the VLC table, wherein the first event is mapped to a first codeword, wherein the first counter is incremented when the first event occurs;
when a second event stored in the VLC table occurs, resetting the first counter to an initial value, wherein the second event is mapped to a second codeword; and
when the first event occurs:
incrementing the first counter;
determining the first counter equals a counter threshold;
responsive to determining the first counter exceeds the counter threshold, mapping the first event to the second codeword and mapping the second event to the first codeword.

10. An apparatus that codes video data, the apparatus comprising a codec unit configured to:
apply a first codeword adaptation scheme to a first group of codewords of a variable length coding (VLC) table to change a mapping of codewords to events in the VLC table; and
apply a second codeword adaptation scheme to a second group of codewords of the VLC table to change the mapping of the codewords to the events in the VLC table.

11. The apparatus of claim 10, wherein the first codeword adaptation scheme comprises a fast adaptation scheme and the second codeword adaptation scheme comprises a counter-based adaptation scheme.

12. The apparatus of claim 10, wherein the codec unit is further configured to:
determine the first group of codewords of the VLC table includes a quantity of codewords equal to a threshold,
wherein the first group of codewords comprises lower ordered codewords in the VLC table,
wherein the second group of codewords comprises higher ordered codewords in the VLC table, and
wherein the lower ordered codewords are mapped to a first group of events in the VLC table that occur with greater frequency than a second group of events in the VLC table mapped to the higher ordered codewords.

13. The apparatus of claim 12, wherein the codec unit is further configured to:
determining an occurrence of a first event, wherein the first event is mapped to a higher ordered codeword in the higher ordered codewords of the VLC table;
determining a second event is mapped to a lower ordered codeword in the lower ordered codewords of the VLC table;
mapping the first event to the lower ordered codeword; and
mapping the second event to the higher ordered codeword.

14. The apparatus of claim 13, wherein the codec unit is further configured to:
responsive to determining the occurrence of the first event, increment a first counter associated with the higher ordered codeword; and
determine the first counter is greater than a second counter associated with the lower ordered codeword.

15. The apparatus of claim 13, wherein the codec unit is further configured to:
responsive to mapping the second event to the higher ordered codeword, associate the second event with the counter.

16. The apparatus of claim 13, wherein the codec unit is further configured to:
wherein the higher ordered codeword comprises a lowest ordered codeword of the higher ordered codewords; and
wherein the lower ordered codeword comprises a highest ordered codeword of the lower ordered codewords.

17. The apparatus of claim 10, wherein the codec unit is further configured to:
receive at a decoder a bitstream of encoded video data that includes at least one codeword.

18. The apparatus of claim 10, wherein at least one of the first codeword adaptation scheme or the second codeword adaptation scheme comprises a modified counter-based adaptation scheme wherein the codec unit is further configured to:
associate a first counter with a first event stored in the VLC table, wherein the first event is mapped to a first codeword, wherein the first counter is incremented when the first event occurs;
when a second event stored in the VLC table occurs, reset the first counter to an initial value, wherein the second event is mapped to a second codeword; and
when the first event occurs:
increment the first counter;
determine the first counter equals a counter threshold;
responsive to determining the first counter exceeds the counter threshold, map the first event to the second codeword and map the second event to the first codeword.

19. A device that codes video data, the device comprising:
means for applying a first codeword adaptation scheme to a first group of codewords of a variable length coding (VLC) table to change a mapping of codewords to events in the VLC table; and
means for applying a second codeword adaptation scheme to a second group of codewords of the VLC table to change the mapping of the codewords to the events in the VLC table.

20. A computer-readable storage medium comprising instructions that upon execution in a processor, cause the processor to code video data, wherein the instructions cause the processor to:
apply a first codeword adaptation scheme to a first group of codewords of a variable length coding (VLC) table to change a mapping of codewords to events in the VLC table; and
apply a second codeword adaptation scheme to a second group of codewords of the VLC table to change the mapping of the codewords to the events in the VLC table.
